(19) United States
(12) Patent Application Publication
(10) Pub. No.: US 2025/0298942 A1
(43) Pub. Date: Sep. 25, 2025

(54) THE ACCURACY OF RESERVOIR FACIES AND PETROPHYSICAL PROPERTY MODELS USING MULTIPLE INFORMATION SOURCES THROUGH QUANTILE MACHINE LEARNING TECHNIQUES

(71) Applicant: Landmark Graphics Corporation, Houston, TX (US)

(72) Inventors: Sebastien Strebelle, Pau (FR); Shreshth Srivastav, Bangalore (IN)

(21) Appl. No.: 18/615,485

(22) Filed: Mar. 25, 2024

(51) Int. Cl. G06F 30/27

(52) U.S. Cl. CPC G06F 30/27

(57) ABSTRACT

Some implementations relate to a method for generating, at least in part by a quantile-trained learning machine, a model of a formation property across one or more subsurface formations of a reservoir using a plurality of external data sources different than the formation property.

### TECHNICAL FIELD

The disclosure generally relates to the field of subsurface earth modeling and, more specifically, facies and petrophysical property modeling using multiple differing secondary data sets.

### BACKGROUND

Three-dimensional facies and petrophysical property models are used to estimate hydrocarbon volume in place and to forecast future production in reservoir development projects. Traditional property models may be built using a limited number of direct measurements from sparse wells. To improve the accuracy of these models and their associated volume and flow performance predictions, it may be important to use additional information sources. These additional information sources may also be referred to as “secondary data” sources. Secondary data may refer to data that has already been collected through primary sources. For example, secondary data may include seismic attributes of one or more subsurface formations. Most traditional geostatistical toolboxes may account for only one type of secondary data. However, doing so may exclude valuable data from reservoir modeling and reservoir development decisions.

### BRIEF DESCRIPTION OF THE DRAWINGS

Implementations of the disclosure may be better understood by referencing the accompanying drawings.

FIG. 1 is a block diagram an example workflow for petrophysical property calculations, according to some implementations.

FIG. 2 is an illustration depicting an example computer, according to some implementations.

FIG. 3 is a flowchart depicting an example method of operations, according to some implementations.

FIG. 4 is a schematic diagram depicting a wireline system with a quantile-trained learning machine that implements distributed computing, according to some implementations.

FIG. 5 is a schematic diagram depicting a drilling rig system with a quantile-trained learning machine that implements distributed computing, according to some implementations.

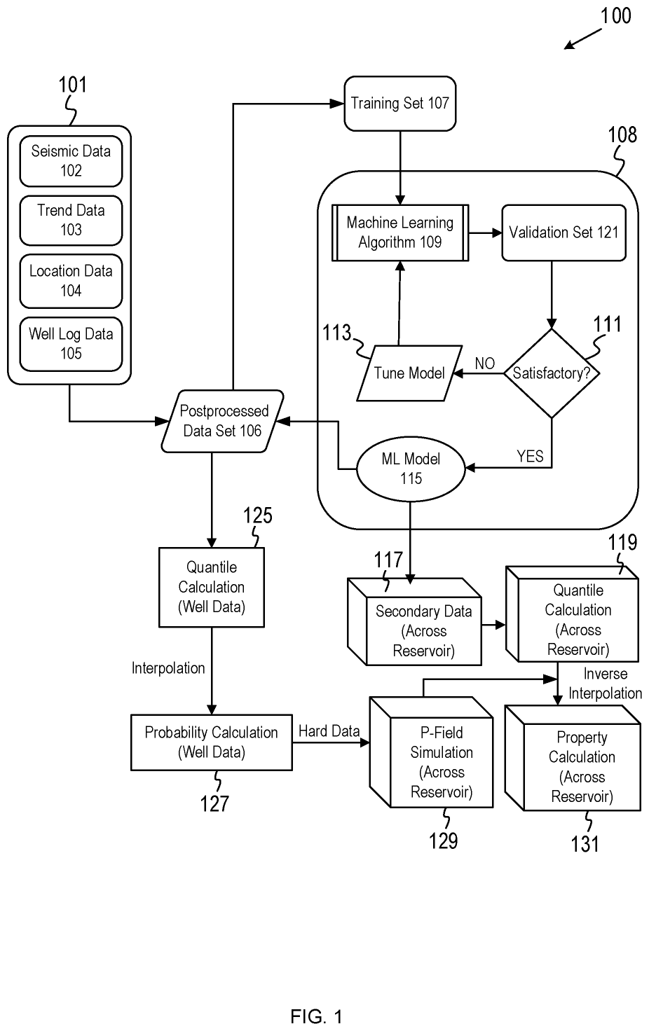

FIGS. 1-5 and the operations described herein are examples meant to aid in understanding example implementations and should not be used to limit the potential implementations or limit the scope of the claims. None of the implementations described herein may be performed exclusively in the human mind nor exclusively using pencil and paper. None of the implementations described herein may be performed without computerized components such as those described herein. Some implementations may perform additional operations, fewer operations, operations in parallel or in a different order, and some operations differently.

### OVERVIEW

Rather than using a single type of secondary data, multiple secondary datasets representing various types of secondary data may be incorporated into facies and petrophysical property modeling using a combination of machine learning algorithms and conventional geostatistical programs. A quantile-trained machine learning model may be used to optimize the amount of information that may be extracted simultaneously from the multiple secondary datasets.

Some implementations may identify secondary data that may inform reservoir facies and petrophysical properties of one or more subsurface formations. Seismic inversion properties such as acoustic impedance obtained after a time-depth conversion are traditionally used, but regional depositional trends may also be used in modeling. X, Y, and Z coordinates may also be considered. A training dataset may be generated from well log data corresponding to the property to be modeled (e.g., porosity, although other properties may be modeled) and from all collocated secondary data. The training dataset may be used to build a machine learning model using an ensemble-based extra-tree regression algorithm. The machine learning model may then be applied to the exhaustive secondary datasets to predict the selected property (e.g., porosity) at each reservoir location. The machine learning model may also provide an uncertainty range with the predictions to form local probability density functions. A geostatistical probability field (P-field) simulation may then be applied to build a three-dimensional property model (e.g., porosity model) from the local probability density functions using a user-specified variogram. The property model may be configured to model either a discrete or a continuous petrophysical property using multiple secondary data sources.

### EXAMPLE ILLUSTRATIONS

FIG. 1 is a block diagram 100 depicting an example workflow for petrophysical property calculations using quantile machine learning techniques, according to some implementations. Multiple data sources 101 are gathered including seismic data 102 (e.g., one or more seismic attributes such as acoustic impedance, elastic impedance, and Lamé parameters), trend data 103 (e.g., regional depositional trends), location data 104 (e.g., absolute x, y, and z spatial coordinates, or relative u, v, w stratigraphic coordinates in a grid), and well log data 105 corresponding to the property to be modeled (e.g., porosity). The multiple data sources 101 may be input into a computer for processing. The seismic data 102 may be spatially combined with the well log data 105 using well-to-seismic tie-up techniques. Of the multiple data sources 101, data sources 102-104 may be referred to as secondary data whereas the well log data 105 may be referred as primary data. Primary data sources, such as the well log data 105, may include direct measurements of rock properties and is scarcer than secondary data. Secondary data sources may be defined as relevant data sources that may have been measured in the past by external or third parties. Examples of secondary data may include existing datasets, research studies, government records, etc. Secondary data may often be available exhaustively, covering a broader area than a measured primary data set directly measured from one or more subsurface formations. While abundant, secondary data may be less precise than primary data.

Secondary data sources such as the seismic data 102, trend data 103, and location data 104 may help constrain the modeling of primary variables, which have been measured only at limited specific spatial locations. Due to limited primary data such as well log data 105, property modeling may utilize the abundant secondary data to help estimate property values at locations far from the primary data locations. Secondary data may be important in adding context to correctly model primary variables. For example, the compaction of a subsurface reservoir at depth may skew porosity data along the Z-axis. Therefore, modeling porosity with respect to secondary data including x-y-z coordinates may improve the accuracy of the resulting porosity model.

The multiple data sources 101 may undergo a postprocessing step, which consists in generating a dataset containing the primary well log data 105 and all the collocated data (data at the same locations as the well log data) from each secondary data source 102, 103 and 104. This postprocessed data set 106 may be split into a training set 107 and a validation set 121. The training set 107 may contain a portion of the primary well log data and the corresponding collocated secondary data (data sources 102-104). The portion of the well data may be sampled from a number of different wells (e.g., 10 wells, although various quantities may be used). The validation set 121 may containing a remaining portion of the primary well log data not included in the training set 107 (e.g., 5 wells, although varying quantities may be used) and the corresponding collocated secondary data.

The training set 107 may be input into a machine learning algorithm 109 to predict the primary variable (e.g., porosity) as a function of all the secondary variables. The machine learning algorithm 109 may include any suitable supervised learning algorithm, or reinforced learning algorithm such as an ensemble-based extra-tree regression algorithm, linear regression, a decision tree model, random forests, logistic regression, ridge regression, gradient boosting regression, XGBoost, K-Means, Hierarchical Clustering, an Apriori algorithm, Gaussian mixture models, LightGBM Regressor, Lasso Regression, any other computerized functionality able to be trained for quantile calculations, etc. The machine learning algorithm 109 may be trained using the training set 107. For example, the machine learning algorithm 109 may be trained using a supervised quantile regression learning technique during a training phase 108, although other techniques may be used. The machine learning algorithm 109 may undergo training and may be tested using cross-validation techniques. These cross-validation techniques may include techniques such as the K-fold cross technique, hold-out technique, leave one out technique, etc. The cross-validation techniques may be used to split the postprocessed data 106 into the validation set 121 and training set 107 and may be used to determine whether the predictive performance of the trained machine learning algorithm is satisfactory. This may be referred to as a training decision 111.

During training, the ML Model 115 may be configured to generate quantile values for a continuous petrophysical property such as porosity. Other properties may be used. The ML Model 115 may predict, based on the training set 107, a range of porosity values at the known well locations, as well as quantile values within the range of porosity values. For example, the ML Model 115 may predict a range of possible porosity values at known locations in the training set 107. The predicted values may be compared to the true values of the petrophysical property at each spatial location in the known data (primary well log data). At one such location, the ML Model 115 may predict a value of porosity and an uncertainty range spanning from 0.2-0.4 porosity units. The ML Model 115 may also compute percentiles across the range of the probabilistic porosity values. The true porosity at that location may be 0.32, meaning the ML Model 115 has made a correct prediction. Predicting a range of values rather than a single point value enables the ML Model 115 to provide uncertainty quantification along with its predictions.

The ML Model 115 may be trained using only data known at well log locations, because these are the only locations where a petrophysical property of interest may be known with certainty. The predictions may be generated conditional to known secondary data such as the seismic data 102, trend data 103, location data 104, etc. The ML Model 115 may be deployed to the validation set 121 for validation of the predictions using well data previously unknown to the ML Model 115. The ML model 115 may be applied to the validation set 121 to generate a full probability distribution via a quantile calculation. A quantile may refer to sorted data split into equal parts—i.e., percentiles may be used to split data into 100 equal parts. In some implementations, other quantiles such as quartiles, deciles, etc. may be used. The ML Model 115 may be applied to the wells within the validation set 121 to generate percentiles (P5, P50, P95) and check the quality of the porosity (or other petrophysical property) range prediction. For example, 90% of the true known porosity values at the well locations belonging to the validation set 121 should fall within the P5-P95 porosity prediction range output by the ML Model 115. If not, the ML Model 115 may re-enter training.

If the predictive functionality of the machine learning algorithm 109 is not satisfactory at the training decision 111, the model may be tuned at a tuning step 113. The tuning step 113 may include adjusting weights, one or more parameters, one or more hyperparameters, updating features, etc. An updated machine learning algorithm 109, after receiving updates via the tuning step 113, may be trained and then validated against the validation set 121 once more. The training phase 108 may be completed a plurality of times to achieve satisfactory results. The machine learning algorithm 109 may be iteratively tuned at the tuning step 113 once satisfactory results are achieved. After iterative tuning and achieving satisfactory results at the training decision 111, a finalized machine learning (ML) model 115 may be generated. Satisfactory results may, for example, include predictions within an error percentage (1-2%) of expected results, although other tolerances may be used.

Once the ML Model 115 has been validated at the known locations corresponding to the well data of the validation set 121, the ML model 115 may be applied to the postprocessed data set 106, which include both the wells within the training set 107 and the validation set 121 to generate a full probability distribution via a quantile calculation 125. A linear interpolation may be applied on the quantiles from the quantile calculation 125 to calculate a percentile corresponding to each true porosity value of the postprocessed data set 106, that is at each depth for both the training and validation wells within the training set 107 and validation set 121, respectively. This percentile may be calculated via a probability calculation 127. The ML Model 115 may predict, for example, a uniform probability distribution for porosity between 0.1-0.2 at one location. The true porosity from the well data may be equal to 0.16; therefore, the probability calculation 127 would select the P60 quantile at this depth, which is equal to a probability of 0.6. Therefore, the probability calculation 127 determines a probability value at all well data locations based on known well data. This probability may be used inversely to determine an estimated property value at a location based on a probability distribution at that location.

The percentile data of all sampled wells from a reservoir, including those of the training set 107 and validation set 121, provided by the probability calculation 127, may be exported to run a geostatistical probability field (P-field) simulation 129. The percentile data may be used as hard data to constrain and guide the simulation 129. For example, some implementations of the simulation may be run conditional to the imported percentile values provided via the probability calculation 127. The P-field simulation 129 may create an ensemble of probabilities with dimensions matching the grid of the target reservoir. The P-field simulation 129 can be performed using different geostatistical simulation algorithms (e.g., Sequential Gaussian Simulation, Turning-Bands Simulation, etc.) across a coordinate grid defining the reservoir of interest. The P-field simulation 129 may be performed across the reservoir grid conditional to the imported data from the probability calculation 127 using a variogram specified by a user.

The user-specified variogram may be used to simulate multiple realizations of the P-field, where each realization provides a different spatial distribution of probabilities. Each simulated realization generated by the P-field simulation 129 may reproduce the spatial heterogeneity observed in the data. A traditional ML model providing singular property value outputs instead of quantile value outputs may underestimate the true heterogeneity that exists in the reservoir as characterized by porosity jumping from high to low values in just a few meters in the subsurface. Capturing the reservoir heterogeneity may be critical for generating reliable reservoir production forecasts and optimizing reservoir development decisions. Therefore, the use of a P-field simulation 129 combined with the porosity ranges output via the quantile-trained ML Model 115 may prevent petrophysical property over-smoothing.

The variogram used to initiate the P-field simulation 129 across the defined reservoir may define the heterogeneity of the reservoir model: a short variogram range may result in a highly heterogeneous reservoir model whereas a long variogram range may result in a relatively homogeneous reservoir model. Thus, rather than the ML Model 115 determining the heterogeneity of the property model, the user retains control of modeling this heterogeneity through the variogram used in the P-field simulation 129. The variogram may allow the user to impose a spatial correlation among property values in the final property model. The variogram may be calculated from different sources, either from well data, seismic data, analog wells, literature, etc. The user-specified variogram may be adjusted based on a depositional environment of the target reservoir. For example, a shallow marine carbonate system may require a variogram of a different range than a fluvial system. Other variograms depicting heterogeneities of other depositional environments may be used. Allowing the user to specify the heterogeneity of the resulting property model may allow for greater flexibility and better representation of the target reservoir's geological context than would approaches that implicitly determine the model's heterogeneity via one or more embedded properties.

The user-specified variogram may be used to calculate probabilities in the P-field simulation 129. Different ranges for the variogram may be tested by a user. In general, a long-range variogram may result in a smooth variation (low heterogeneity) between probability values across the reservoir, whereas a short-range variogram may induce higher variations when account for short-scale heterogeneity. The resulting heterogeneity of the P-field simulation 129 may be propagated to a final petrophysical property model across the reservoir.

While the P-field simulation 129 is performed, the quantile-trained ML Model 115 may also generate quantile estimations of the petrophysical property to be modeled across the target reservoir. The secondary data set 117 may be a subset of the secondary data set within the multiple data sources 101 across the defined reservoir grid. The secondary data set 117 may consist of a volumetric representation of the seismic data 102, the trend data 103 and the location data 104 across the defined reservoir.

The ML model 115 may be applied to the secondary data set 117 to generate petrophysical property percentiles via a quantile calculation 119 across the defined reservoir. For example, this may include generating, via the ML model 115, porosity percentiles such as P5, P50, P95, etc. at each grid location in the reservoir grid, forming a local probability function. This calculation may occur at all locations in the reservoir, both at well locations where the true porosity is known and at coordinates in the grid where porosity is unknown.

The P-field simulation 129 across the reservoir may be processed with quantile calculation 119 applied to the secondary data set 117 to yield a petrophysical property calculation across the reservoir of interest.

Lower probability value predictions from the P-field simulation 129 may indicate that the porosity at an example location may be on the lower end of the predicted distribution modeled by the quantile Calculation 119. On the contrary, a large probability value at a location may indicate that the location's porosity may be on the high side of the estimated property distribution. A probability prediction of 0.05 from the P-field simulation may correspond to the P5 quantile, whereas a 0.95 prediction may correspond to a P95 quantile. Inverse interpolation may be applied to the P-field simulation 129 and quantile calculation 119 to yield a 3D formation property model. In some implementations, the inverse interpolation may utilize inverse distance weighted interpolation. However, other inverse interpolation techniques, such as inverse distance squared weighted interpolation, may be used.

Thus, to simulate a petrophysical property across a target reservoir, the quantile-trained ML Model 115 may first determine a probabilistic range of values for the petrophysical property at each location within a coordinate grid. At one such location, the ML Model may determine that the porosity there is within a range of 0.2-0.3. The ML Model 115 may also determine quantiles within the porosity range prediction at every location within a three-dimensional coordinate grid defining a reservoir of interest via the quantile calculation 119. The quantile calculations across the reservoir may be combined with the P-field simulation 129 across the three-dimensional coordinate grid. Thus, every location within the reservoir may include a predicted petrophysical property (e.g., porosity) distribution with associated quantiles, and a probability value of the property range prediction.

At the property calculation 131, a formation property across the reservoir of interest may be simulated. The calculated probability value at each location may determine an assigned petrophysical property value at the location. For example, the P-field simulation 129 may determine a probability of 80%, which corresponds to a P80 quantile. Given that the ML Model 115 may provide an estimated porosity range of 0.2-0.3, a unique porosity value of 0.28 may be assigned to this location based on the P80 quantile. This may be repeated across all locations in the reservoir to yield a complete petrophysical realization across the target reservoir. In some implementations, the petrophysical property simulation may be a 3D porosity model for the target reservoir that may be visualized and interpreted using a geoscience software or any suitable computerized functionality. In some implementations, the 3D porosity model of the reservoir may be at a sub-seismic resolution. The property calculation 131 may be used to calculate a volume of oil and gas in the target reservoir, may be used to run fluid simulations within the subsurface, may be used for informed decisions with regard to drilling additional wells, etc.

In the case of a discrete property such as depositional facies, the ML model 115 may be trained to provide the probability of each facies instead of a petrophysical property distribution and its corresponding quantiles. The ML model 115 may be applied to the secondary data set 117 to predict the probability of each facies at each location of the defined target reservoir. The quantile calculation 125, the probability calculation 127, and the P-field simulation 129 may not be needed for facies simulation. Instead, the property calculation 131 may be performed using a variogram-based indicator simulation algorithm such as Truncated Gaussian Simulation or Pluri-Gaussian Simulation, conditioned by the facies well log data 105 and the facies probabilities provided by the ML Model 115.

In some implementations, in the case of facies simulation, the property calculation 131 may be performed without the user-specified variogram. For example, the property calculation 131 may instead be determined via multiple-point statistics (MPS) simulation. The MPS simulation may generate facies models that replicate the spatial features present in a training image (TI); therefore, the training image, as determined by a user, may describe the heterogeneity in the resulting simulation(s). The MPS simulation process may be repeated to yield an ensemble of realizations, where each realization captures a different plausible geological scenario.

Most traditional software solutions in reservoir modeling offer techniques to integrate secondary data. For example, seismic attributes may be calibrated to facies well log data to generate a 3D facies probability cube that may be used to guide geostatistical simulations of facies. In another example, traditional techniques to integrate secondary data may include the use of collocated cokriging, cloud transforms, etc. to model the relationship between a petrophysical property and a secondary data set. This technique may then generate a 3D model of the petrophysical property constrained by the relationship to the secondary data set. In the majority of cases, only one secondary data set, most often a seismic attribute such as acoustic impedance, is used in modeling.

Other traditional techniques that use more than one secondary data set may be limited in their use. For example, some machine-learning algorithms may be used to estimate petrophysical properties (porosity in particular) from multiple secondary data sets. In these algorithms, the secondary data sets, comparable to the multiple data sources 101, may require an initial estimate of the petrophysical and/or formation property itself. This may also be referred to as an embedded property, and the embedded property may be obtained via kriging and the removal of some well data. These traditional techniques for integrating multiple secondary data sets of various types of data may simulate a petrophysical property directly without the use of a geostatistical parameters. Geostatistics may only be used in computing the embedded properties, which results in a simulation similar to a black box—inputs are entered, results are output, but the functionality of the ML model remains largely devoid of user input or control.

However, ML models such as the ML model 115 (and the operations, functionalities, etc. of the block diagram 100) may not utilize embedded properties. Instead, the multiple secondary data sources 102-104 (which are all different from the property to be modeled) may be used by the ML model 115 to model either discrete properties like facies or continuous properties, such as porosity, across a reservoir. The ML model 115 may allow a user to retain additional control during property simulations via the above-described variogram. The user-provided variogram may be used to simulate the desired petrophysical property at a heterogeneity fine-tuned for the reservoir of interest. However, in some implementations, alternative geostatistical programs not requiring a variogram may also be used (e.g., multiple-point statistics simulation).

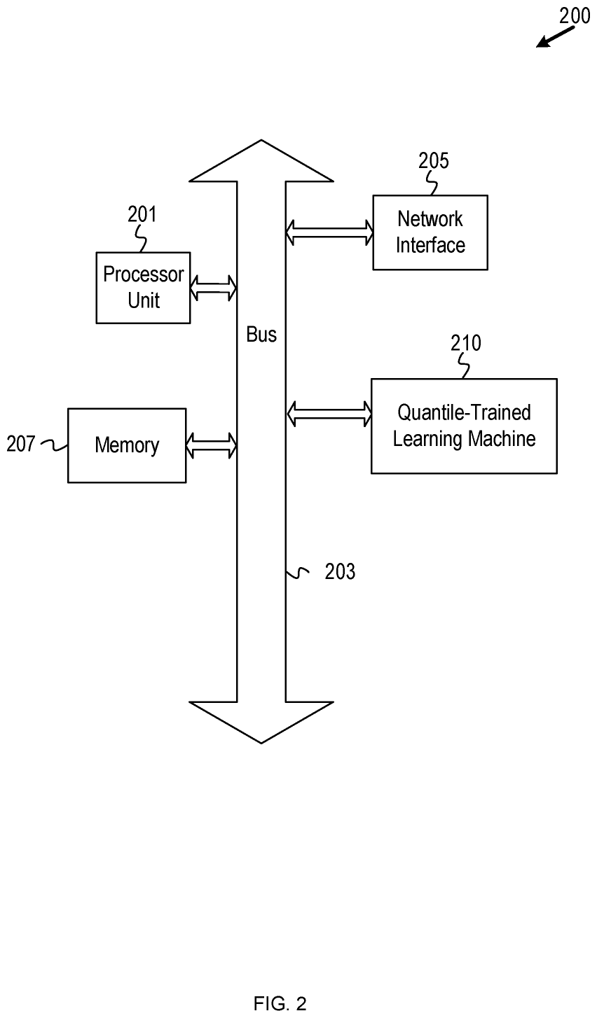

FIG. 2 is an illustration depicting an example computer 200, according to some implementations. The computer 200 may include a processor 201 (possibly including multiple processors, multiple cores, multiple nodes, and/or implementing multi-threading, etc.). The computer system may include memory 207. The memory 207 may be system memory or any one or more of the above already described possible realizations of machine-readable media. The computer system may also include a bus 203 and a network interface 205. The system may communicate via transmissions to and/or from remote devices via the network interface 205 in accordance with a network protocol corresponding to the type of network interface, whether wired or wireless and depending upon the carrying medium. In addition, a communication or transmission may involve other layers of a communication protocol and or communication protocol suites (e.g., transmission control protocol, Internet Protocol, user datagram protocol, virtual private network protocols, etc.).

The system may implement a quantile-trained learning machine 210 in hardware, software, and/or other logic configured to perform the operations described herein. In some implementations, the quantile-trained learning machine 210 may be embodied as instructions executable on the processor 201. The quantile-trained learning machine 210 may be similar to the ML Model 115 of FIG. 1. Any one of the previously described functionalities may be partially (or entirely) implemented in hardware and/or on the processor 201. For example, the functionality may be implemented with an application specific integrated circuit, in logic implemented in the processor 201, in a co-processor on a peripheral device or card, etc. Further, realizations may include fewer or additional components not illustrated in FIG. 2 (e.g., video cards, audio cards, additional network interfaces, peripheral devices, etc.). The processor 201 and the network interface 205 are coupled to the bus 203. Although illustrated as being coupled to the bus 203, the memory 207 may be coupled to the processor 201.

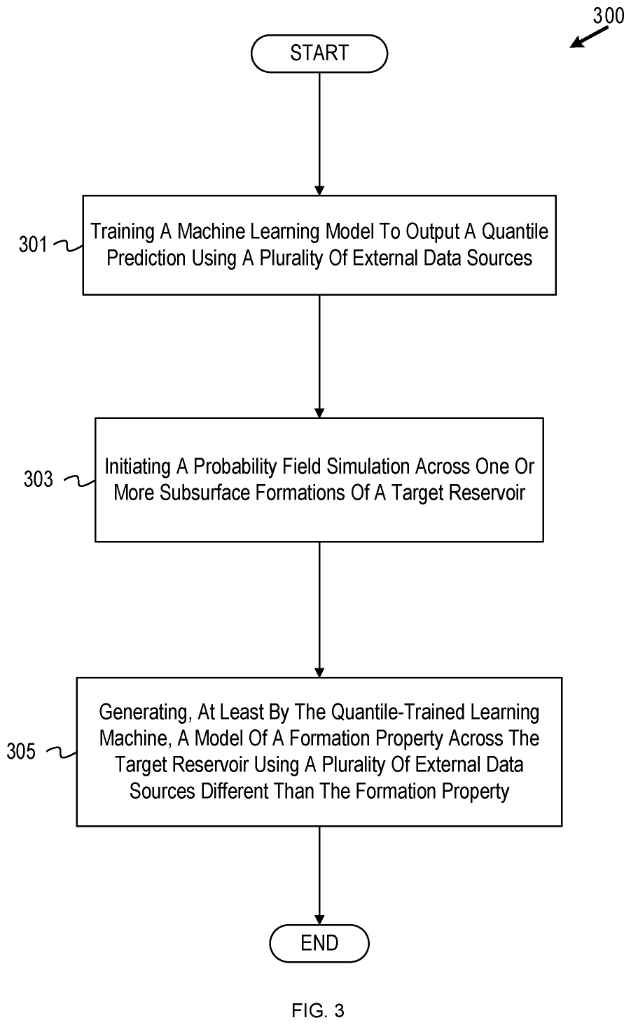

FIG. 3 is a flowchart 300 depicting an example method of operations, according to some implementations. Operations of the flowchart 300 may be performed by software, firmware, hardware, or a combination thereof (such as the quantile-trained learning machine 210). Such operations are described with reference to FIGS. 1-2. However, such operations may be performed by other systems or components. The operations of the flowchart 300 begin at block 301.

At block 301, the ML Model 115 may be trained to output a quantile prediction using a plurality of external data sources different than the formation property to be modeled. For example, the ML Model 115 may be configured to output a quantile prediction of a continuous formation property (e.g., porosity, permeability, any other petrophysical property having a continuous range of values, etc.) or the probability of a discrete formation property (facies such as sandstone, shale, a lithology of one or more subsurface formations, etc.). The quantile predictions may be conditional to one or more external data sources (i.e., secondary data) such as the multiple data sources 101. In some implementations, porosity may be simulated across the reservoir, and the simulation may use secondary data such as seismic data 102, trend data 103, location data 104, etc. In simulations of other formation properties, such as permeability, secondary porosity data may be included in the multiple data sources 101. Flow progresses to block 303.

At block 303, the quantile-trained learning machine 210 initiates the P-field simulation 129 across one or more subsurface formations of a target reservoir. In some implementations, the P-field simulation 129 may be initiated by a user-specified variogram and may be conditional to known data at well locations. Other implementations may utilize MPS simulation for using the facies probabilities estimated by the ML Model 115 and simulating discrete formation property models. Flow progresses to block 305.

As block 305, the ML Model 115 generates a model of a formation property across the target reservoir using the multiple data sources 101 which are different from the modeled formation property. For example, the ML Model 115 may generate a 3D porosity model of a target reservoir based on integrating multiple secondary data sources such as the seismic data 102, trend data 103, and location data 104. The ML Model 115 may generate the 3D porosity model by determining a plausible porosity distribution and quantile distribution of the plausible porosity values at each location in the reservoir. A probability value at each location may also be determined via the P-field simulation 129. A formation property value at each reservoir location may be assigned based on the estimated probability and a quantile value corresponding to the probability value. Therefore, each location may be assigned a simulated property value, forming a three-dimensional model of the formation property. In some implementations, the three-dimensional model of the formation property may be utilized, at least in part, to perform a wellbore operation, a fluid sampling operation, a drilling operation, etc. Flow of flowchart 300 ceases.

### Example Systems

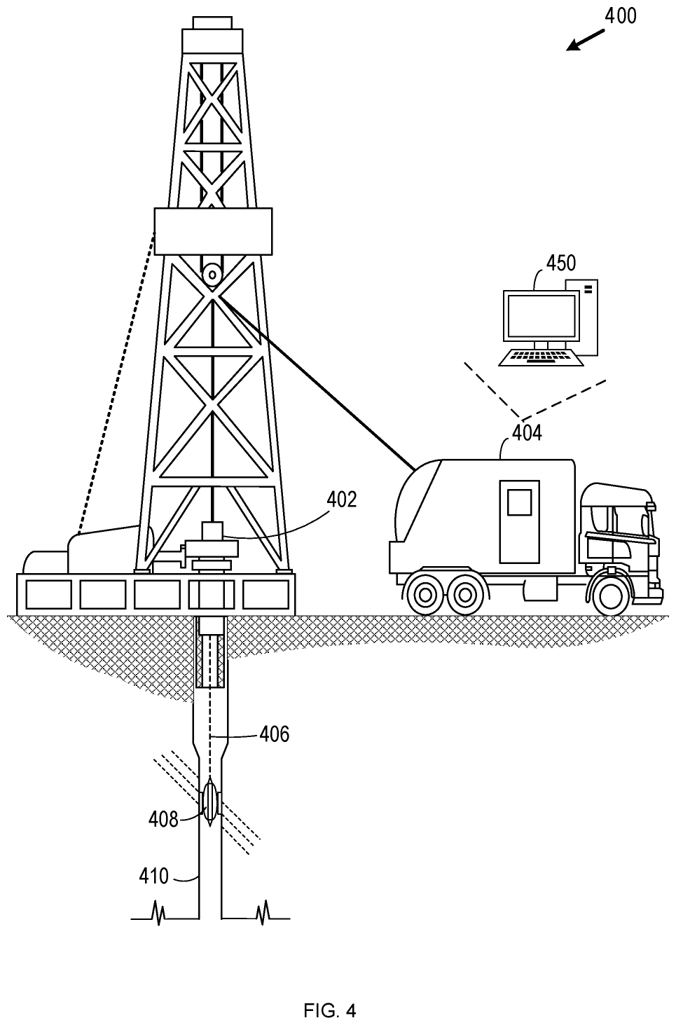

FIG. 4 is a schematic diagram depicting a wireline system with a quantile-trained learning machine that implements distributed computing, according to some implementations. A computer system 450 may include the quantile-trained learning machine 210. A wireline system 400 may be used in an illustrative logging environment with a drill string removed, in accordance with some implementations of the present disclosure.

Subterranean operations may be conducted using a wireline system 400 once a drill string has been removed from a borehole 410, though, at times, some or all of the drill string may remain in the borehole 410 during logging with the wireline system 400. The wireline system 400 may include one or more logging tools 408 that may be suspended in the borehole 410 by a conveyance 406 (e.g., a cable, slickline, or coiled tubing). The conveyance 406 may include any hardware suitable to lower a logging tool 408 to a target depth. The logging tool 408 may be communicatively coupled to the conveyance 406. The conveyance 406 may include conductors for transporting power to the wireline system 420 and telemetry from the logging tool 408 to a logging facility 404. The logging facility 404 may include the computer system 450, the computer system 450 capable of generating formation property simulations using quantile machine learning techniques as described herein (e.g., with respect to FIGS. 1-3). Alternatively, the conveyance 406 may lack a conductor, as is often the case using slickline or coiled tubing, and the wireline system 400 may contain a control unit 402 that contains memory, one or more batteries, and/or one or more processors for performing operations and storing measurements.

In some implementations, the control unit 402 may be positioned at the surface, in the borehole (e.g., in the conveyance 406 and/or as part of the logging tool 408) or both (e.g., a portion of the processing may occur downhole, and a portion may occur at the surface). The control unit 402 may include a control system or a control algorithm. In some implementations, a control system, an algorithm, or a set of machine-readable instructions may cause the control unit 402 to generate and provide an input signal to one or more elements of the logging tool 408, such as the sensors along the logging tool 408. The input signal may cause the sensors to be active or to output signals indicative of sensed properties. The logging facility 404, while depicted as a vehicle/mobile configuration in FIG. 4, may include any other suitable structure. The logging facility 404 may collect measurements from the logging tool 408, and may include computing facilities for controlling, processing, or storing the measurements gathered by the logging tool 408. The computing facilities may be communicatively coupled to the logging tool 408 by way of the conveyance 406 and may operate similarly to the control unit 402.

The logging tool 408 includes a mandrel and a number of extendible arms coupled to the mandrel. One or more pads are coupled to each of the extendible arms. Each of the pads may have a surface facing radially outward from the mandrel. Additionally, at least a sensor is disposed on the surface of each pad. During operation, the extendible arms are extended outwards to a wall of the borehole to extend the surface of the pads outward against the wall of the borehole. The sensors of the pads of each extendible arm may detect image data to create captured images of the formation surrounding the borehole.

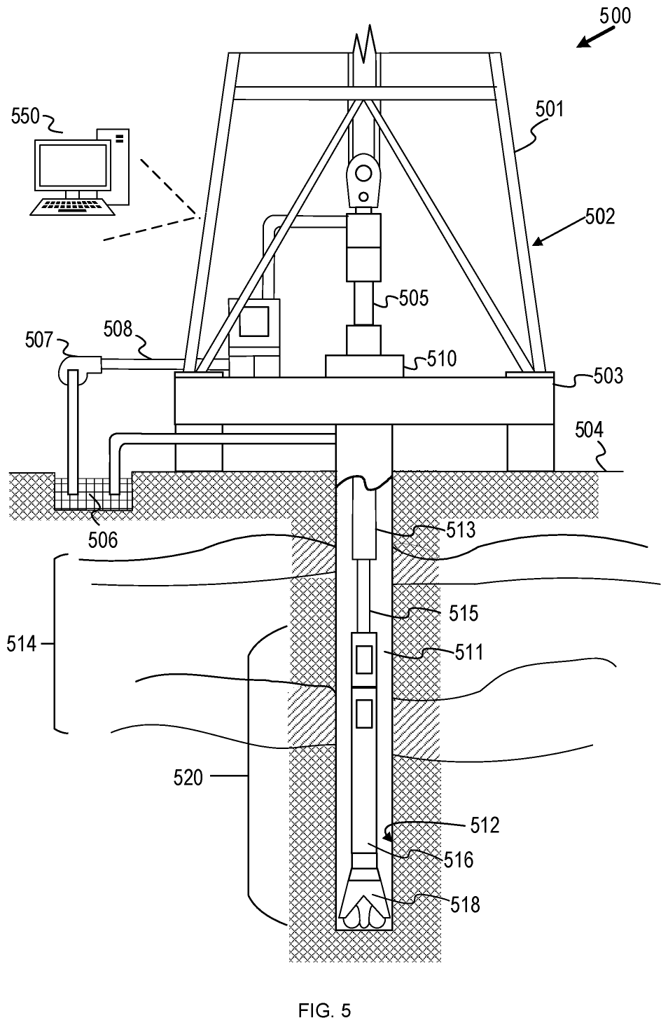

FIG. 5 is a schematic diagram depicting a drilling rig system with a quantile-trained learning machine that implements distributed computing, according to some implementations. A drilling system 500 may include a drilling rig 502 located at the surface 504 of a borehole 512. Drilling of oil and gas wells may commonly be carried out using a plurality of drill pipes 515 connected together so as to form a drill string that is lowered through a rotary table 510 into the borehole 512. A drilling platform 503 may be equipped with a derrick 501 that supports a hoist. A computer system 550 (having the quantile-trained learning machine 210) may be communicatively coupled to any measurements devices attached to the drilling system 500.

The drilling rig 502 may thus provide support for the drill string. The drill string may be conveyed through the rotary table 510 for drilling the borehole 512 through one or more subsurface formations 514. In some implementations, the one or more subsurface formations may include the target reservoir to be simulated by the quantile-trained learning machine 210. The drill string may include a kelly 505, drill pipe 515, and a bottom hole assembly 520 which may be located at the lower portion of the drill string.

A bottom hole assembly 520 may include drill collars 513, a downhole tool 516, and a drill bit 518. The drill bit 518 may operate to create the borehole 512 by penetrating the surface 504 and subsurface formations 514. The downhole tool 516 may comprise any of a number of different types of tools including MWD tools, LWD tools, etc. In some implementations, the downhole tool 516 may be configured to measure at least one of the multiple data sources 101. Some implementations may utilize the downhole tool 516 and a plurality of seismic tools at the surface to collect the seismic data 102. However, other data and data collection techniques may be measured and used, respectively.

During drilling operations, the drill string (which may include the kelly 505, the drill pipe 515, and the bottom hole assembly 520) may be rotated by the rotary table 510. In addition to, or alternatively, the bottom hole assembly 520 may also be rotated by a motor (e.g., a mud motor) that is located down hole. The drill collars 513 may be used to add weight to the drill bit 518 and increase a rate of penetration (ROP) of the drill bit 518. The drill collars 513 may also operate to stiffen the bottom hole assembly 520, allowing the bottom hole assembly 520 to transfer the added weight to the drill bit 518, which may further assist the drill bit 518 in penetrating the surface 504 and subsurface formations 514.

During drilling operations, a mud pump 507 may pump drilling fluid (sometimes known by those of ordinary skill in the art as “drilling mud”) from a mud pit 506 through a conduit 508 into the drill pipe 515 and down to the drill bit 518. The drilling fluid may flow out from the drill bit 518 and be returned to the surface 504 through an annular area 511 between the drill pipe 515 and the sides of the borehole 512. The drilling fluid may then be returned to the mud pit 506, where such fluid may be filtered. In some implementations, the drilling fluid may be used to cool the drill bit 518, as well as to provide lubrication for the drill bit 518 during drilling operations. Additionally, the drilling fluid may be used to remove subsurface formation 514 cuttings created by operating the drill bit 518.

In some implementations, data collected from the above systems, including the wireline system 400 and the drilling system 500, may be incorporated into the computer systems 450 and 550. Computations, such as any of the simulated property models output via the ML Model 115, as well as other operations described in FIGS. 1-3, may be completed by the computer systems 450, 550. These computations may be used to optimize or change operational parameters of the systems 400, 500. In some implementations, one or more subsurface operations may be performed based on predictions of the quantile-trained learning machine 210. For example, an operator may perform a drilling operation based on a prediction from the quantile-trained learning machine 210 of the computer system 550.

While the aspects of the disclosure are described with reference to various implementations and exploitations, it will be understood that these aspects are illustrative and that the scope of the claims is not limited to them. In general, techniques for formation property simulation using a quantile-trained learning machine as described herein may be implemented with facilities consistent with any hardware system or hardware systems. Many variations, modifications, additions, and improvements may be possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” may be infringed with only one of the listed items, multiple of the listed items, and one or more of the items in the list and another item not listed. As an example, “at least one of: a, b, or c” is intended to cover: a, b, c, a-b, a-c, b-c, and a-b-c.

The various illustrative logics, logical blocks, modules, circuits, and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described throughout. Whether such functionality is implemented in hardware or software depends upon the particular application and design constraints imposed on the overall system.

The hardware and data processing apparatus used to implement the various illustrative logics, logical blocks, modules and circuits described in connection with the implementations disclosed herein may be implemented or performed with a general purpose single- or multi-chip processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor or any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more implementations, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, e.g., one or more modules of computer program instructions stored on a computer storage media for execution by, or to control the operation of, a computing device.

If implemented in software, the functions may be stored on or transmitted over as one or more instructions or code on a computer-readable medium. The processes of a method or algorithm disclosed herein may be implemented in a processor-executable instructions which may reside on a computer-readable medium. Computer-readable media includes both computer storage media and communication media including any medium that may be enabled to transfer a computer program from one place to another. Storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-Ray™ disc where disks usually reproduce data magnetically, while discs reproduce data optically with lasers. Combinations also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Certain features that are described in this specification in the context of separate implementations also may be implemented in combination in a single implementation. Conversely, various features that are described in the context of a single implementation also may be implemented in multiple implementations separately or in any suitable sub-combination. Moreover, although features may be described as acting in certain combinations and even initially claimed as such, one or more features from a claimed combination may in some cases be excised from the combination, and the claimed combination may be directed to a sub-combination or variation of a sub-combination.

While operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, some operations may be omitted and/or other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described should not be understood as requiring such separation in all implementations, and the described program components and systems may generally be integrated together in a single software product or packaged into multiple software products. Additionally, other implementations are within the scope of the following claims. In some cases, the actions recited in the claims may be performed in a different order and still achieve desirable results.

Unless otherwise specified, use of the terms “up,” “upper,” “upward,” “uphole,” “upstream,” or other like terms shall be construed as generally away from the bottom, terminal end of a well; likewise, use of the terms “down,” “lower,” “downward,” “downhole,” or other like terms shall be construed as generally toward the bottom, terminal end of the well, regardless of the wellbore orientation. Use of any one or more of the foregoing terms shall not be construed as denoting positions along a perfectly vertical axis. In some instances, a part near the end of the well may be horizontal or even slightly directed upwards. Unless otherwise specified, use of the terms “subsurface formation” or “subterranean formation” shall be construed as encompassing both areas below exposed earth and areas below earth covered by water such as ocean or fresh water.

### EXAMPLE IMPLENTATIONS

Implementation #1: A method comprising: generating, at least in part by a quantile-trained learning machine, a model of a formation property across one or more subsurface formations of a reservoir using a plurality of external data sources different than the formation property.
Implementation #2: The method of Implementation 1, further comprising: initiating, via a user-specified variogram, a probability field simulation of the formation property across the one or more subsurface formations.
Implementation #3: The method of any one or more of Implementations 1-2, wherein the user-specified variogram determines a heterogeneity of the probability field simulation.
Implementation #4: The method of any one or more of Implementations 1-3, further comprising: generating, via multiple-point statistical simulation, the model of the formation property across the one or more subsurface formations of the reservoir, wherein the formation property is a discrete formation property.
Implementation #5: The method of any one or more of Implementations 1-4, wherein the formation property is a continuous formation property.
Implementation #6: The method of any one or more of Implementations 1-5, wherein the plurality of external data sources include location data, trend data, and seismic data of the one or more subsurface formations.
Implementation #7: The method of any one or more of Implementations 1-6, further comprising: predicting, via the quantile-trained learning machine, an uncertainty range of the formation property at each location in the reservoir; determining, via the quantile-trained learning machine, a probability at each location in the reservoir, wherein the probability includes a quantile value; and assigning, at each location in the reservoir, a value of the formation property based, at least in part, on the uncertainty range of the formation property and the probability at each location in the reservoir.
Implementation #8: A system comprising: a processor; and a computer-readable medium having instructions executable by the processor, the instructions including: instructions to generate, at least in part by a quantile-trained learning machine, a model of a formation property across one or more subsurface formations of a reservoir using a plurality of external data sources different than the formation property.
Implementation #9: The system of Implementation 8, further comprising: instructions to initiate, via a user-specified variogram, a probability field simulation of the formation property across the one or more subsurface formations, wherein the user-specified variogram determines a heterogeneity of the probability field simulation.
Implementation #10: The system of any one or more of Implementations 8-9, further comprising: instructions to generate, via multiple-point statistical simulation, the model of the formation property across the one or more subsurface formations of the reservoir, wherein the formation property is a discrete formation property.
Implementation #11: The system of any one or more of Implementations 8-10, wherein the formation property is a continuous formation property.
Implementation #12: The system of any one or more of Implementations 8-11, wherein the plurality of external data sources include location data, trend data, and seismic data of the one or more subsurface formations.
Implementation #13: The system of any one or more of Implementations 8-12, further comprising: instructions to predict, via the quantile-trained learning machine, an uncertainty range of the formation property at each location in the reservoir; instructions to determine, via the quantile-trained learning machine, a probability at each location in the reservoir, wherein the probability includes a quantile value; and instructions to assign, at each location in the reservoir, a value of the formation property based, at least in part, on the uncertainty range of the formation property and the probability at each location in the reservoir.
Implementation #14: One or more non-transitory machine-readable media including instructions executable by a processor to cause the processor to perform a simulation across a reservoir, the instructions comprising: instructions to generate, at least in part by a quantile-trained learning machine, a model of a formation property across one or more subsurface formations of the reservoir using a plurality of external data sources different than the formation property.
Implementation #15: The machine-readable media of Implementation 14, further comprising: instructions to initiate, via a user-specified variogram, a probability field simulation of the formation property across the one or more subsurface formations, wherein the user-specified variogram determines a heterogeneity of the probability field simulation.
Implementation #16: The machine-readable media of any one or more of Implementations 14-15, further comprising: instructions to generate, via multiple-point statistical simulation, the model of the formation property across the one or more subsurface formations of the reservoir.
Implementation #17: The machine-readable media of any one or more of Implementations 14-16, wherein the formation property is a discrete formation property.
Implementation #18: The machine-readable media of any one or more of Implementations 14-17, wherein the formation property is a continuous formation property.
Implementation #19: The machine-readable media of any one or more of Implementations 14-18, wherein the plurality of external data sources include location data, trend data, and seismic data of the one or more subsurface formations.
Implementation #20: The machine-readable media of any one or more of Implementations 14-19, further comprising: instructions to predict, via the quantile-trained learning machine, an uncertainty range of the formation property at each location in the reservoir; instructions to determine, via the quantile-trained learning machine, a probability at each location in the reservoir, wherein the probability includes a quantile value; and instructions to assign, at each location in the reservoir, a value of the formation property based, at least in part, on the uncertainty range of the formation property and the probability at each location in the reservoir.

What is claimed is:

1. A method comprising:
generating, at least in part by a quantile-trained learning machine, a model of a formation property across one or more subsurface formations of a reservoir using a plurality of external data sources different than the formation property.

2. The method of claim 1, further comprising:
initiating, via a user-specified variogram, a probability field simulation of the formation property across the one or more subsurface formations.

3. The method of claim 2, wherein the user-specified variogram determines a heterogeneity of the probability field simulation.

4. The method of claim 1, further comprising:
generating, via multiple-point statistical simulation, the model of the formation property across the one or more subsurface formations of the reservoir, wherein the formation property is a discrete formation property.

5. The method of claim 1, wherein the formation property is a continuous formation property.

6. The method of claim 1, wherein the plurality of external data sources include location data, trend data, and seismic data of the one or more subsurface formations.

7. The method of claim 1, further comprising:
predicting, via the quantile-trained learning machine, an uncertainty range of the formation property at each location in the reservoir;
determining, via the quantile-trained learning machine, a probability at each location in the reservoir, wherein the probability includes a quantile value; and
assigning, at each location in the reservoir, a value of the formation property based, at least in part, on the uncertainty range of the formation property and the probability at each location in the reservoir.

8. A system comprising:
a processor; and
a computer-readable medium having instructions executable by the processor, the instructions including:
instructions to generate, at least in part by a quantile-trained learning machine, a model of a formation property across one or more subsurface formations of a reservoir using a plurality of external data sources different than the formation property.

9. The system of claim 8, further comprising:
instructions to initiate, via a user-specified variogram, a probability field simulation of the formation property across the one or more subsurface formations, wherein the user-specified variogram determines a heterogeneity of the probability field simulation.

10. The system of claim 8, further comprising:
instructions to generate, via multiple-point statistical simulation, the model of the formation property across the one or more subsurface formations of the reservoir, wherein the formation property is a discrete formation property.

11. The system of claim 8, wherein the formation property is a continuous formation property.

12. The system of claim 8, wherein the plurality of external data sources include location data, trend data, and seismic data of the one or more subsurface formations.

13. The system of claim 8, further comprising:
instructions to predict, via the quantile-trained learning machine, an uncertainty range of the formation property at each location in the reservoir;
instructions to determine, via the quantile-trained learning machine, a probability at each location in the reservoir, wherein the probability includes a quantile value; and
instructions to assign, at each location in the reservoir, a value of the formation property based, at least in part, on the uncertainty range of the formation property and the probability at each location in the reservoir.

14. One or more non-transitory machine-readable media including instructions executable by a processor to cause the processor to perform a simulation across a reservoir, the instructions comprising:
instructions to generate, at least in part by a quantile-trained learning machine, a model of a formation property across one or more subsurface formations of the reservoir using a plurality of external data sources different than the formation property.

15. The machine-readable media of claim 14, further comprising:
instructions to initiate, via a user-specified variogram, a probability field simulation of the formation property across the one or more subsurface formations, wherein the user-specified variogram determines a heterogeneity of the probability field simulation.

16. The machine-readable media of claim 14, further comprising:
instructions to generate, via multiple-point statistical simulation, the model of the formation property across the one or more subsurface formations of the reservoir.

17. The machine-readable media of claim 16, wherein the formation property is a discrete formation property.

18. The machine-readable media of claim 14, wherein the formation property is a continuous formation property.

19. The machine-readable media of claim 14, wherein the plurality of external data sources include location data, trend data, and seismic data of the one or more subsurface formations.

20. The machine-readable media of claim 14, further comprising:
instructions to predict, via the quantile-trained learning machine, an uncertainty range of the formation property at each location in the reservoir;
instructions to determine, via the quantile-trained learning machine, a probability at each location in the reservoir, wherein the probability includes a quantile value; and
instructions to assign, at each location in the reservoir, a value of the formation property based, at least in part, on the uncertainty range of the formation property and the probability at each location in the reservoir.
